(19) United States
(12) Patent Application Publication
(10) Pub. No.: US 2026/0182090 A1
(43) Pub. Date: Jun. 25, 2026

(54) LIGHT EMITTING DEVICE AND MODULE HAVING THE SAME

(71) Applicant: SEOUL VIOSYS CO., LTD., Ansan-si (KR)

(72) Inventor: Hongjae YOO, Ansan-si (KR)

(73) Assignee: SEOUL VIOSYS CO., LTD., Ansan-si (KR)

(21) Appl. No.: 19/426,633

(22) Filed: Dec. 19, 2025

Related U.S. Application Data
(60) Provisional application No. 63/738,115, filed on Dec. 23, 2024.

(51) Int. Cl. H10H 20/815; H10H 20/812; H10H 20/825

(52) U.S. Cl. CPC H10H 20/815; H10H 20/812; H10H 20/825

(57) ABSTRACT

The present invention discloses a light emitting device including a first conductivity type semiconductor layer, a second conductivity type semiconductor layer, and an active layer disposed between the first conductivity type semiconductor layer and the second conductivity type semiconductor layer, in which the active layer includes a multi quantum well structure of well layers and barrier layers that are alternately disposed, and a peak wavelength of emitted light emitted from the active layer is 620 nm to 640 nm, and a ratio of the peak wavelength to a thickness (nm) from a barrier layer adjacent to the second conductivity type semiconductor layer to the second conductivity type semiconductor layer has a value between 3.4 and 3.8.

### TECHNICAL FIELD

The present invention relates to a light emitting device and a light emitting module having the same.

### BACKGROUND ART

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, it has been rapidly replacing a conventional light source. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current may flow from the p-electrode pad through the semiconductor layers to the n-electrode pad, and light generated through recombination of electrons and holes in the active layer may be emitted.

### DISCLOSURE

### Technical Problem

The present invention aims to provide a light emitting device and a light emitting module having the same that emit high-efficiency red light.

The present invention aims to provide a light emitting device and a light emitting module having the same that implement red light using a single InGaN-based material.

The present invention aims to provide a light emitting device and a light emitting module having the same that is suitable for a monolithic integrated structure that forms all red, green, and blue (RGB) pixels in a chip unit by implementing a red light emitting device using a same substrate as that of blue and green light emitting devices in which InGaN-based materials are used.

The present invention aims to provide a light emitting device and a light emitting module having the same that implement a high-quality white LED through the above-described monolithic integration without an additional color conversion material or a complex chip transfer process.

The present invention aims to provide a light emitting device and a light emitting module having the same in which lattice mismatch and strain resulting therefrom occurring in an active layer are alleviated.

The present invention aims to provide a high-efficiency long-wavelength red light emitting device and a light emitting module having the same in which a generation of crystalline defects is suppressed by alleviating strain and internal quantum efficiency (IQE) and external quantum efficiency (EQE) are improved.

The present invention aims to provide a light emitting device and a light emitting module having the same having low efficiency drop phenomenon even at a high driving current, and having high light output and high luminous intensity characteristics.

The present invention aims to provide a light emitting device and a light emitting module having the same having excellent thermal stability and long-term reliability.

The present invention aims to provide a light emitting device and a light emitting module having the same that simplify a manufacturing process and reduce production costs by allowing all RGB pixels to be formed through a single epitaxial growth process

### Technical Solution

An embodiment of the present invention discloses a light emitting device including a first conductivity type semiconductor layer, a second conductivity type semiconductor layer, and an active layer disposed between the first conductivity type semiconductor layer and the second conductivity type semiconductor layer.

In an embodiment, the active layer may include a multi quantum well structure of well layers and barrier layers that are alternately disposed.

In an embodiment, a difference between an In composition (%) of the well layer and an In composition (%) of the second conductivity type semiconductor layer may be 20% or more.

In an embodiment, the second conductivity type semiconductor layer may include a buffer line for alleviating lattice stress with the well layer.

In an embodiment, the buffer line may have a slope with respect to a thickness direction of the second conductivity type semiconductor layer and extend from one surface of the second conductivity type semiconductor layer toward the other surface thereof.

In an embodiment, a ratio of the peak wavelength to a thickness (nm) of the well layer may have a value between 135 and 256.

In an embodiment, the first conductivity type semiconductor layer may be a semiconductor layer doped with an n-type dopant, and the second conductivity type semiconductor layer may be a semiconductor layer doped with a p-type dopant.

In an embodiment, the light emitting device may further include a pre-strain layer disposed between the first conductivity type semiconductor layer and the active layer.

In an embodiment, a ratio of the peak wavelength to a thickness (nm) of the pre-strain layer may have a value between 0.8 and 1.

In an embodiment, the pre-strain layer may include a first pre-strain layer disposed on one surface of the first conductivity type semiconductor layer and including GaN, a second pre-strain layer disposed on one surface of the first pre-strain layer and including InGaN, and a superlattice pre-strain layer disposed on one surface of the second pre-strain layer.

In an embodiment, the first pre-strain layer may include a first-1 pre-strain layer and a first-2 pre-strain layer having a thickness smaller than that of the first-1 pre-strain layer.

In an embodiment, the first pre-strain layer may be doped with Si.

In an embodiment, an In composition of the second pre-strain layer may have a value between 1% and 10%.

In an embodiment, the superlattice pre-strain layer may include a plurality of pairs in which InGaN and GaN are alternately stacked.

In an embodiment, an In composition of the superlattice pre-strain layer may be less than or equal to that of the second pre-strain layer.

In an embodiment, the active layer may further include a cap layer disposed between the well layer and the barrier layer and including Al.

In an embodiment, the cap layer may include a first cap layer disposed on one surface of the well layer and including AlN, and a second cap layer disposed on one surface of the first cap layer and including AlGaN.

In an embodiment, the first conductivity type semiconductor layer may include a first-1 conductivity type semiconductor layer including GaN, a first-2 conductivity type semiconductor layer disposed on one surface of the first-1 conductivity type semiconductor layer and including Al, and a first-3 conductivity type semiconductor layer disposed on one surface of the first-2 conductivity type semiconductor layer and including GaN.

In an embodiment, the second conductivity type semiconductor layer may include a second-1 conductivity type semiconductor layer including GaN, a second-2 conductivity type semiconductor layer disposed on one surface of the second-1 conductivity type semiconductor layer and including Al, and a second-3 conductivity type semiconductor layer disposed on one surface of the second-2 conductivity type semiconductor layer and including GaN.

Another embodiment of the present invention discloses a light emitting device including a first conductivity type semiconductor layer, a second conductivity type semiconductor layer, and an active layer disposed between the first conductivity type semiconductor layer and the second conductivity type semiconductor layer, in which the active layer includes a multi quantum well structure of well layers and barrier layers that are alternately disposed, and a dominant wavelength of emitted light emitted from the active layer is 610 nm to 630 nm, and a ratio of the dominant wavelength to a thickness (nm) from a barrier layer adjacent to the second conductivity type semiconductor layer to the second conductivity type semiconductor layer has a value between 3.4 and 3.8.

In an embodiment, a difference between an In composition (%) of the well layer and an In composition (%) of the second conductivity type semiconductor layer may be 20% or more.

In an embodiment, the second conductivity type semiconductor layer may include a buffer line for alleviating lattice stress with the well layer.

### Advantageous Effect

The present invention may provide a light emitting device and a light emitting module having the same that emit high-efficiency red light.

The present invention may provide a light emitting device and a light emitting module having the same that implement red light using a single InGaN-based material.

The present invention may provide a light emitting device and a light emitting module having the same that is suitable for a monolithic integrated structure that forms all red, green, and blue (RGB) pixels in a chip unit by implementing a red light emitting device using a same substrate as that of blue and green light emitting devices in which InGaN-based materials are used.

The present invention may provide a light emitting device and a light emitting module having the same that implement a high-quality white LED through the above-described monolithic integration without an additional color conversion material or a complex chip transfer process.

The present invention may provide a light emitting device and a light emitting module having the same in which lattice mismatch and strain resulting therefrom occurring in an active layer are alleviated.

The present invention may provide a high-efficiency long-wavelength band red light emitting device and a light emitting module having the same in which a generation of crystalline defects is suppressed by alleviating strain, and internal quantum efficiency (IQE) and external quantum efficiency (EQE) are improved.

The present invention may provide a light emitting device and a light emitting module having the same having low efficiency drop phenomenon even at a high driving current, and having high light output and high luminous intensity characteristics.

The present invention may provide a light emitting device and a light emitting module having the same having excellent thermal stability and long-term reliability.

The present invention may provide a light emitting device and a light emitting module having the same that is configured to simplify a manufacturing process and reduce production costs by allowing all RGB pixels to be formed through a single epitaxial growth process.

### BRIEF DESCRIPTION OF DRAWING

FIG. 1 is a cross-sectional view showing a light emitting device according to an embodiment of the present invention.

FIG. 2 is an enlarged view showing A of FIG. 1.

FIG. 3 is a cross-sectional view showing a first conductivity type semiconductor layer of the light emitting device of FIG. 1.

FIG. 4 is a cross-sectional view showing a portion of an active layer of the light emitting device of FIG. 1.

FIG. 5 is a cross-sectional view showing a second conductivity type semiconductor layer of the light emitting device of FIG. 1.

FIG. 6 is a cross-sectional view showing a pre-strain layer of the light emitting device of FIG. 1.

FIG. 7 is a cross-sectional view showing a portion of a light emitting device according to another embodiment of the present invention.

FIG. 8A is a cross-sectional view showing a light emitting module according to a first embodiment of the present invention.

FIG. 8B is a modified example of FIG. 8A.

FIG. 9 is a plan view showing a light emitting module according to a second embodiment of the present invention.

FIG. 10 is a side view showing a light emitting module according to a third embodiment of the present invention.

FIG. 11 is a plan view showing a light emitting module according to a fourth embodiment of the present invention.

FIG. 12 is an exploded perspective view showing a light emitting module according to a fifth embodiment of the present invention.

FIG. 13 is a cross-sectional view showing a portion of a light emitting module according to a sixth embodiment of the present invention.

FIG. 14 is a side view showing a portion of a light emitting module according to a seventh embodiment of the present invention.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device of the present invention and a light emitting module having the same will be described in detail through accompanying drawings.

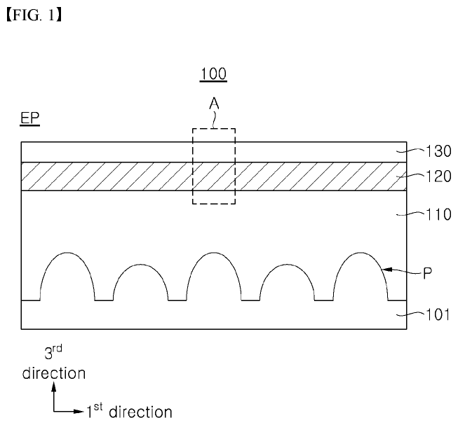

FIG. 1 illustrates a semiconductor layer EP of a light emitting device 100 according to an embodiment of the present invention, in which the semiconductor layer EP may include a first conductivity type semiconductor layer 110, a second conductivity type semiconductor layer 130, and an active layer 120 disposed between the first conductivity type semiconductor layer 110 and the second conductivity type semiconductor layer 130.

The first conductivity type semiconductor layer 110 may include a phosphide or nitride semiconductor such as (Al, Ga, In)P or (Al, Ga, In)N, and may be disposed on a substrate 101.

Herein, the substrate 101 is not limited to a specific substrate as long as it is a substrate capable of growing or disposing a semiconductor, may include, for example, a heterogeneous substrate such as a sapphire substrate, a silicon substrate, a silicon carbide substrate, or a spinel substrate, and may also include a homogeneous substrate such as a gallium nitride substrate, an aluminum nitride substrate, or others. One surface of the substrate 101 may be a flat surface, or may be patterned to form a concave-convex or protrusions (P). The substrate 101 may be removed after forming the semiconductor layer, or the semiconductor layer may be bonded to the substrate 101.

For example, the first conductivity type semiconductor layer 110 is a semiconductor layer doped with a first conductivity type dopant, and for example, the first conductivity type semiconductor layer 110 may be formed of an InₓAl_{y}Ga_{(1-x-y)}N (0≤x≤0, 0≤y≤1, 0≤x+y≤1) doped with Si as the first conductivity type dopant or InₓAl_{y}Ga_{(1-x-y)}P (0≤x≤0, 0≤y≤1, 0≤x+y≤1).

In addition, the first conductivity type semiconductor layer 110 may be doped as n-type by including one or more impurities such as Si, C, Ge, Sn, Te, Pb, or others. However, the inventive concepts are not limited thereto, and the first conductivity type semiconductor layer 110 may be doped with an opposite conductivity type, including a p-type dopant. A doping concentration of the first conductivity type dopant may be 1×10¹⁸ atoms/cm³ to 1×10²⁰ atoms/cm³.

The first conductivity type semiconductor layer 110 may be configured as a single layer, or may include a plurality of layers. The first conductivity type semiconductor layer 110 may further include a nucleation layer and a buffer layer. In addition, the first conductivity type semiconductor layer 110 may further include a superlattice layer. The superlattice layer may be formed over the first conductivity type semiconductor layer 110. In addition, the first conductivity type semiconductor layer 110 may further include a contact layer, a modulation doping layer, an electron injection layer, or others.

For example, referring to FIG. 3, the first conductivity type semiconductor layer 110 may be a semiconductor layer doped with an n-type dopant, and may include a first-1 conductivity type semiconductor layer 112, first-2 conductivity type semiconductor layers 114 and 116 disposed on one surface of the first-1 conductivity type semiconductor layer 112 and having a band gap energy higher than that of the first-1 conductivity type semiconductor layer 112, and a first-3 conductivity type semiconductor layer 118 disposed on one surface of the first-2 conductivity type semiconductor layers 114 and 116 and having a band gap energy lower than those of the first-2 conductivity type semiconductor layers 114 and 116.

For example, the first conductivity type semiconductor layer 110 may include the first-1 conductivity type semiconductor layer 112 including GaN, the first-2 conductivity type semiconductor layers 114 and 116 disposed on one surface of the first-1 conductivity type semiconductor layer 112 and including Al, and the first-3 conductivity type semiconductor layer 118 disposed on one surface of the first-2 conductivity type semiconductor layers 114 and 116 and including GaN.

A thickness of the first-1 conductivity type semiconductor layer 112 may be 2500 nm to 3500 nm. A doping concentration of a first conductivity type dopant of the first-1 conductivity type semiconductor layer 112 may be 1×10²⁰ atoms/cm³ to 2×10²⁰ atoms/cm³.

The first-2 conductivity type semiconductor layers 114 and 116 may be layers disposed on one surface of the first-1 conductivity type semiconductor layer 112 and including Al. In addition, the first-2 conductivity type semiconductor layers 114 and 116 may be doped with a first conductivity type dopant, but the inventive concepts are not limited thereto.

The first-2 conductivity type semiconductor layers 114 and 116 may be provided in a plurality of numbers. For example, FIG. 3 exemplarily illustrates that the first-2 conductivity type semiconductor layers 114 and 116 are formed of two layers, but the present invention is not limited thereto.

One of the first-2 conductivity type semiconductor layers 114 and 116 may include a first layer 114 having a relatively higher band gap energy, and the other may include a second layer 116 having a relatively lower band gap energy. For example, the first layer 114 may be an AlN layer, and the second layer 116 may be an AlGaN layer.

The first layer 114 may be disposed on one surface of the first-1 conductivity type semiconductor layer 112. The first layer 114 may further include Ga. The first layer 114 may have a composition of AlₓG₍₁₋ₓ₎N (0<x≤1).

A thickness of the first layer 114 may be 2 nm to 3 nm.

An Al composition of the first layer 114 may be 20% or more. A doping concentration of a first conductivity type dopant of the first layer 114 may be 1×10¹⁹ atoms/cm³ or less.

The second layer 116 may be disposed on one surface of the first layer 114. The second layer 116 may have a composition of AlₓG₍₁₋ₓ₎N (0<x<1). The second layer 116 may further include In.

A thickness of the second layer 116 may be larger than that of the first layer 114 for strain adjustment. For example, the thickness of the second layer 116 may be between 15 nm and 30 nm.

An Al composition of the second layer 116 may be less than that of the first layer 114. In addition, the second layer 116 may have a gradation structure in which the Al composition gradually changes depending on a position thereof.

A doping concentration of a first conductivity type dopant of the second layer 116 may be 1×10¹⁹ atoms/cm³ or less.

The first layer 114 and the second layer 116 may form one pair, and a plurality of pairs may be sequentially stacked.

The first-3 conductivity type semiconductor layer 118 may disposed on one surface of the first-2 conductivity type semiconductor layers 114 and 116 and may include GaN. For example, the first-3 conductivity type semiconductor layer 118 may be disposed on one surface of the second layer 116.

A thickness of the first-3 conductivity type semiconductor layer 118 may be 1.5 μm to 2.0 μm. A doping concentration of a first conductivity type dopant of the first-3 conductivity type semiconductor layer 118 may be 1×10²⁰ atoms/cm³ or less.

The second conductivity type semiconductor layer 130 may include a phosphide or nitride semiconductor such as (Al, Ga, In)P or (Al, Ga, In)N, and may be grown using a technique such as MOCVD, MBE, HVPE, or others. The second conductivity type semiconductor layer 130 may be doped with a second conductivity type dopant having a conductivity type opposite to that of the first conductivity type semiconductor layer 130. For example, the second conductivity type semiconductor layer 130 may be doped as p-type by including an impurity such as Mg. The second conductivity type semiconductor layer 130 may be formed of, for example, InₓAl_{y}Ga_{(1-x-y)}N (0≤x≤1, 0≤y≤1, 0≤x+y≤1) or InₓAl_{y}Ga_{(1-x-y)}P (0≤x≤1, 0≤y≤1, 0≤x+y≤1).

In addition, the second conductivity type semiconductor layer 130 may be configured as a single layer having a composition such as p-InₓAl_{y}Ga_{(1-x-y)}N (0≤x≤1, 0≤y≤1, 0≤x+y≤1) or p-InₓAl_{y}Ga_{(1-x-y)}P (0≤x≤1, 0≤y≤1, 0≤x+y≤1) or may include a plurality of layers. In addition, the second conductivity type semiconductor layer 130 may further include a layer including Al therein. In addition, the second conductivity type semiconductor layer 130 may further include a superlattice layer. In addition, the second conductivity type semiconductor layer 130 may further include a second conductivity type contact layer.

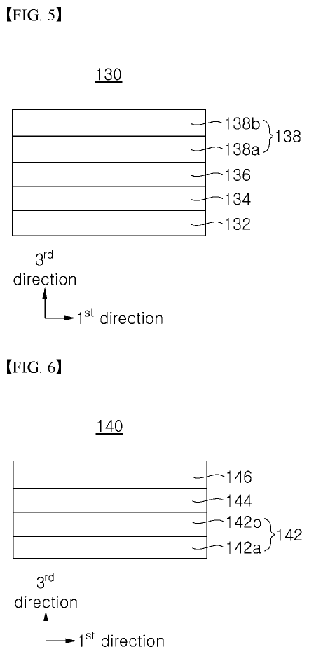

For example, referring to FIG. 5, the second conductivity type semiconductor layer 130 is a semiconductor layer doped with a p-type dopant, and may include a second-1 conductivity type semiconductor layer 132 including GaN or GaP, second-2 conductivity type semiconductor layers 134 and 136 disposed on one surface of the second-1 conductivity type semiconductor layer 132 and having a band gap energy larger than that of the second-1 conductivity type semiconductor layer 132, and a second-3 conductivity type semiconductor layer 138 disposed on one surface of the second-2 conductivity type semiconductor layers 134 and 136 and including GaN or GaP.

A thickness of the second-1 conductivity type semiconductor layer 132 may be between 10 nm and 25 nm. A doping concentration of a second conductivity type dopant of the second-1 conductivity type semiconductor layer 132 may be 1×10²⁰ atoms/cm³ to 2×10²⁰ atoms/cm³.

The second-2 conductivity type semiconductor layers 134 and 136 may be disposed on one surface of the second-1 conductivity type semiconductor layer 132 and may be Al(Ga)N layers including Al. In addition, the second-2 conductivity type semiconductor layers 134 and 136 may be doped with a second conductivity type dopant, but the inventive concepts are not limited thereto.

The second-2 conductivity type semiconductor layers 134 and 136 may be provided in a plurality of numbers. For example, FIG. 5 exemplarily illustrates that the second-2 conductivity type semiconductor layers 134 and 136 is formed of two of a first layer 134 and a second layer 136, but the present invention is not limited thereto.

The first layer 134 may be an AlN layer, and the second layer 136 may be an AlGaN layer.

The first layer 134 may be disposed on one surface of the second-1 conductivity type semiconductor layer 132. The first layer 134 may further include Ga. The first layer 134 may have a composition of AlₓG₍₁₋ₓ₎N (0<x≤1) or AlₓG₍₁₋ₓ₎P (0<x≤1).

A thickness of the first layer 134 may be between 2 nm and 5 nm.

An Al composition of the first layer 134 may be 20% or more. A doping concentration of a second conductivity type dopant of the first layer 134 may be 1×10¹⁹ atoms/cm³ or less.

The second layer 136 may be disposed on one surface of the first layer 134. The second layer 136 may have a composition of AlₓG₍₁₋ₓ₎N (0<x<1) or AlₓG₍₁₋ₓ₎P (0<x<1). The second layer 136 may further include In.

A thickness of the second layer 136 may be larger than that of the first layer 134 for strain adjustment. For example, the thickness of the second layer 136 may be between 15 nm and 30 nm.

An Al composition of the second layer 136 may be less than that of the first layer 134. In addition, the second layer 136 may have a gradation structure in which the Al composition gradually changes depending on a position thereof.

A doping concentration of a second conductivity type dopant of the second layer 136 may be 1×10¹⁹ atoms/cm³ or less.

The first layer 134 and the second layer 136 may form one pair, and a plurality of pairs may be sequentially stacked.

The second-3 conductivity type semiconductor layer 138 may be disposed on one surface of the second-2 conductivity type semiconductor layers 134 and 136 and may include GaN or GaP. For example, the second-3 conductivity type semiconductor layer 138 may be disposed on one surface of the second layer 136.

The second-3 conductivity type semiconductor layer 138 may include a plurality of layers. For example, the second-3 conductivity type semiconductor layer 138 may include a first layer 138a and a contact layer 138b. Further, the first layer 138a may be a p-GaN layer.

A thickness of the first layer 138a may be between 50 nm and 200 nm. A doping concentration of a second conductivity type dopant of the first layer 138a may be between 5×10¹⁹ atoms/cm³ to 1×10²⁰ atoms/cm³.

A thickness of the contact layer 138b may be between 10 nm and 20 nm. A doping concentration of a second conductivity type dopant of the contact layer 138b may be 5×10²⁰ atoms/cm³ to 1×10²¹ atoms/cm³.

The active layer 120 may be a light emitting layer disposed between the first conductivity type semiconductor layer 110 and the second conductivity type semiconductor layer 130. The active layer 120 may be disposed on one surface of the first conductivity type semiconductor layer 110.

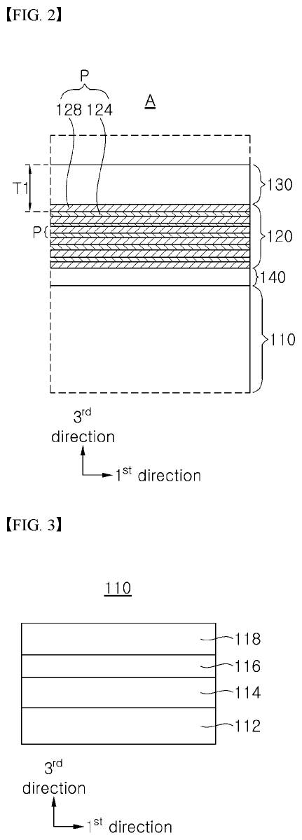

Referring to FIG. 2, the active layer 120 may include a quantum well structure (QW) including at least two barrier layers 128 and at least one well layer 124. Alternatively, the active layer 120 may include a multi quantum well structure (MQW) of the barrier layers 124 and the well layers 128 alternately disposed. Adjacent barrier layer 124 and well layer 128 may form one pair P, and the active layer 120 may include a plurality of sequentially stacked pairs P. Adjacent barrier layer and well layer may form one pair. The active layers 304, 305, and 306 may include a plurality of pairs.

The well layer 124 and the barrier layer 128 may be formed of, for example, a semiconductor material having a composition formula of InₓAl_{y}Ga_{(1-x-y)}N (0≤x≤1, 0≤y≤1, 0≤x+y≤1) or InₓAl_{y}Ga_{(1-x-y)}P (0≤x≤1, 0≤y≤1, 0≤x+y≤1).

A wavelength of light emitted from the active layer 120 may be adjusted by controlling a composition ratio of materials forming the well layer 124. A composition and a thickness of the well layer 124 may determine the wavelength of light generated. In particular, by adjusting the composition of the well layer 124, the active layer 120 that generates ultraviolet light, blue light, red light, or green light may be provided. For example, the well layer 124 may include a high In composition. A difference between an In composition (%) of the well layer 124 and an In composition (%) of the second conductivity type semiconductor layer 130 may be 20% or more. Through this, long-wavelength red light may be emitted from the active layer 120. A peak wavelength of the emitted light may be formed between 600 nm and 650 nm. A dominant wavelength of the emitted light may be 590 nm to 640 nm.

The first conductivity type semiconductor layer 110, the active layer 120, and the second conductivity type semiconductor layer 130 may be a light emitting structure that emits light having a preset peak wavelength as a semiconductor stack. That is, the semiconductor stack may emit light of blue, green, red, and others. For example, a semiconductor stack that emits red light may have a dominant wavelength and a peak wavelength within a red wavelength range. In detail, the semiconductor stack may have the dominant wavelength and the peak wavelength between 600 nm and 650 nm. A peak wavelength of red light may be a wavelength longer than the dominant wavelength.

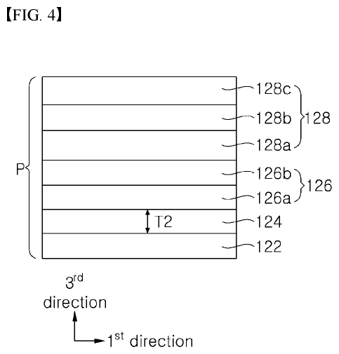

Meanwhile, referring to FIG. 4, the active layer 120 may further include a pre-well layer 122 between the first conductivity type semiconductor layer 110 and the well layer 124. The pre-well layer 122 may be an InGaN layer and have a thickness of 1 nm or less.

The active layer 120 may further include a cap layer 126 disposed between the well layer 124 and the barrier layer 128 and including Al. The cap layer 126 may be directly disposed over the well layer 124, thereby enhancing a confinement effect of carriers (holes and electrons) and enabling fine adjustment of lattice strain.

The cap layer 126 may include a first cap layer 126a disposed on one surface of the well layer 124 and including AlN, and a second cap layer 126b disposed on one surface of the first cap layer 126a and including AlGaN.

A thickness of the first cap layer 126a may be between 1 nm and 2.5 nm. The first cap layer 126a may be a layer that does not include Ga. Since AlN has a widest bandgap in the III-nitride series, a very high energy barrier may be formed by disposing a thin AlN layer directly over an InGaN well layer 124. The high energy barrier may block leakage current or overflow phenomenon in which electrons injected into the well layer 124 escape to the barrier layer 128.

In particular, since such electron leakage is a main cause of efficiency reduction in a long-wavelength (red) light emitting device 100 in which a depth of the well layer 124 is relatively shallow, efficiency may be maximized through the AlN-based first cap layer 126a.

In addition, the barrier layer 128 may be grown at a temperature much higher than that of the well layer 124. In this case, a problem of a quality of the well layer 124 being degraded and an emission wavelength being changed due to a decomposition or out-diffusion of indium (In) in the InGaN well layer 124 at a high temperature may be prevented by a thermally stable first cap layer 126a. That is, the first cap layer 126a may serve as a protection layer that protects the well layer 124 from a high-temperature process.

A thickness of the second cap layer 126b may be between 1 nm and 2.5 nm. The thickness of the second cap layer 126b may be larger than that of the first cap layer 126a. AlN, which is the first cap layer 126a, has a small lattice constant, while GaN, which is the barrier layer 128, has a relatively large lattice constant. The second cap layer 126b formed of AlGaN may serve as an intermediate layer, that is a strain buffer layer, which gradually connects lattice constants between these two layers. Through this, crystalline defects that can occur due to a sharp lattice mismatch between the first cap layer 126a and a GaN barrier layer 128 may be suppressed, and a stability of an entire epitaxial structure may be improved.

The double cap layer 126a and 126 structure, through a functional combination of the first cap layer 126a responsible for carrier confinement and protecting the well layer 124, and the second cap layer 126b alleviating lattice strain, may overcome structural and electrical limitations of a red InGaN well layer 124 including a high concentration of indium (In) and improve an efficiency and reliability of the light emitting device 100.

In addition, the barrier layer 128 may have a stack structure in which a plurality of sub-barrier layers 128a, 128b, and 128c formed under different growth conditions is stacked.

The plurality of sub-barrier layers 128a, 128b, and 128c may be formed at different growth temperatures and play functionally separate roles. For example, the barrier layer 128 may include a first sub-barrier layer (GaN Barrier 1) 128a, a second sub-barrier layer (GaN Barrier 2) 128b, and a third sub-barrier layer (GaN Barrier 3) 128c sequentially disposed on the cap layer 126.

The well layer 124 including the high concentration of indium (In) and the cap layer 126 including Al may be very thermally sensitive. When an entire barrier layer 128 is grown at once at a high temperature, due to its heat, the indium (In) in the well layer 124 may be decomposed or out-diffused, thereby seriously degrading a quality of the well layer 124. To prevent this, the first sub-barrier layer 128a may be grown at a relatively low temperature to serve as a protection layer that minimizes thermal damage to the well layer 124 and the cap layer 126 thereunder.

On the other hand, as a GaN layer is grown at a higher temperature, a mobility of atoms increases, thereby having excellent crystallinity and a flat surface. The excellent crystallinity and flat surface may determine a quality of a next well layer 124 to be grown thereon. Therefore, the second and third sub-barrier layers 128b and 128c may be grown at a temperature higher than that of the first sub-barrier layer 128a, thereby improving the crystallinity of the barrier layer 128 itself and providing a high-quality flat surface for a growth of the next well layer 124.

For optimal strain distribution and structural stability, a thickness of the first sub-barrier layer 128a may be formed smaller than a sum of thicknesses of the second sub-barrier layer 128b and the third sub-barrier layer 128c.

The pre-well layer 122 to the barrier layer 128 may form one pair P, and a total thickness of the pair P may be between 10 nm and 20 nm. A number of the pairs P may be formed between 5 and 12.

Meanwhile, the light emitting device 100 of the present invention may include a very high concentration of indium (In) in the well layer 124 within the active layer 120 so as to implement red light. This may induce a large lattice stress between the active layer 120 and the second conductivity type semiconductor layer 130 grown thereon. When such stress is not effectively alleviated, serious crystalline defects such as misfit dislocations may be generated directly within the active layer 120, thereby significantly reducing a radiation efficiency.

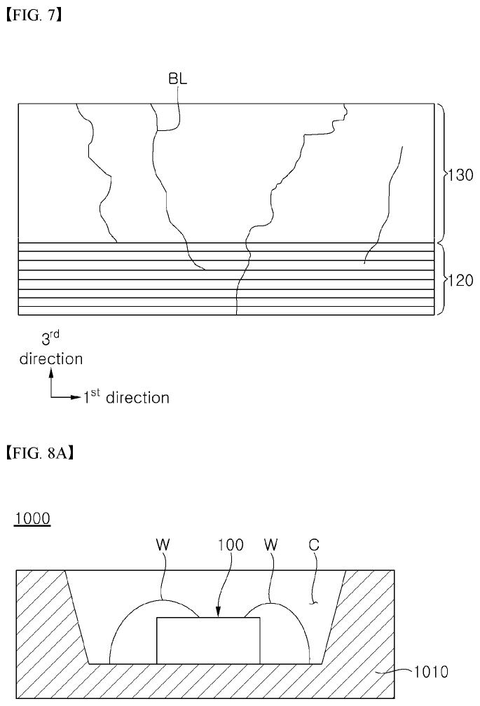

Referring to FIG. 7, to solve this problem, the second conductivity type semiconductor layer 130 may include a buffer line BL to alleviate the lattice stress with the well layer 124.

The buffer line BL is a line-shaped structure formed inside the second conductivity type semiconductor layer 130, and may be formed to effectively alleviate and disperse stress energy accumulated in the active layer 120.

For example, the buffer line BL may have a slope with respect to a thickness direction of the second conductivity type semiconductor layer 130 and extend from one surface of the second conductivity type semiconductor layer 130 toward the other surface thereof.

The buffer line BL may have a constant slope in the thickness direction, and may start near an interface (one surface) with the active layer 120 and extend obliquely or in a curved shape toward an upper portion (the other surface) of the second conductivity type semiconductor layer 130. Through this inclined structure, the buffer line BL may be lengthily formed and stress energy may be gradually dispersed over a wider region. Some of the buffer lines BL may extend to an interior of the active layer 120.

Compressive stress energy generated in the active layer 120 may be released and alleviated along the buffer line BL as the second conductivity type semiconductor layer 130 grows. That is, the buffer line BL may function as ‘an energy outlet’ that prevents stress from being concentrated, and through this, the well layer 124 where light is generated may be maintained in a high-quality state with relatively few defects.

Meanwhile, the light emitting device 100 may further include a pre-strain layer 140 disposed between the first conductivity type semiconductor layer 110 and the active layer 120. In FIG. 1, the pre-strain layer 140 may be omitted as an optional configuration.

The pre-strain layer 140 may adjust and alleviate the lattice strain in advance such that the active layer 120 to be grown subsequently, particularly a red quantum well layer 124 including a high concentration of indium (In) and inducing a large lattice stress, can grow while maintaining high-quality crystallinity. The pre-strain layer 140 may have a stack structure formed of a plurality of layers.

For example, the pre-strain layer 140 may include a first pre-strain layer 142 disposed on one surface of the first conductivity type semiconductor layer 110 and including GaN, a second pre-strain layer 144 disposed on one surface of the first pre-strain layer 142 and including InGaN, and a superlattice pre-strain layer 146 disposed on one surface of the second pre-strain layer 144. The first pre-strain layer 142, the second pre-strain layer 144, and the superlattice pre-strain layer 146 may be sequentially stacked from a side of the first conductivity type semiconductor layer 110.

The first pre-strain layer 142 may provide a stable base for subsequent layer growth. The first pre-strain layer 142 may be doped with a first conductivity type dopant, for example, Si. The doping concentration may be 1×10¹⁷ atoms/cm³ to 3×10¹⁸ atoms/cm³.

The first pre-strain layer 142 may include a first-1 pre-strain layer 142a and a first-2 pre-strain layer 142b having a thickness smaller than that of the first-1 pre-strain layer 142a.

The thickness of the first-1 pre-strain layer 142a may be 250 nm to 300 nm. The first-1 pre-strain layer 142a may be doped with a first conductivity type dopant. The doping concentration may be 1×10¹⁷ atoms/cm³ to 3×10¹⁸ atoms/cm³.

The first-2 pre-strain layer 142b may be a recovery layer having a thickness smaller than that of the first-1 pre-strain layer 142a. The thickness of the first-2 pre-strain layer 142b may be between 10 nm and 30 nm.

The second pre-strain layer 144 may be an InGaN single layer disposed on one surface of the first pre-strain layer 142. An In composition of the second pre-strain layer 144 may have a relatively low value between 1% and 10%. The second pre-strain layer 144 may be doped with a first conductivity type dopant, for example, Si. The doping concentration may be 5×10¹⁷ atoms/cm³ to 3×10¹⁸ atoms/cm³. The second pre-strain layer 144 may be subjected to modulation doping having a non-uniform first-conductivity dopant concentration distribution.

The second pre-strain layer 144 may gradually introduce strain into the lattice before growing the active layer 120 including a high concentration of indium.

The superlattice pre-strain layer 146 may be a superlattice layer disposed on one surface of the second pre-strain layer 144.

The superlattice pre-strain layer 146 may include a plurality of pairs in which InGaN and GaN are alternately stacked. For example, the superlattice pre-strain layer 146 may include a structure in which an InGaN layer and a GaN layer are alternately stacked in 2 to 4 periods, but this is exemplary and the inventive concepts are not limited thereto.

A thickness of the superlattice pre-strain layer 146 may be between 300 nm and 415 nm.

An In composition of the superlattice pre-strain layer 146 may be less than or equal to the In composition of the second pre-strain layer 144.

The superlattice pre-strain layer 146 may effectively disperse and finely adjust the lattice strain, thereby minimizing an occurrence of crystalline defects in the active layer 120 to be grown thereover.

The pre-strain layer 140 may gradually accommodate and alleviate the lattice stress that occurs during the growth of a red light emitting active layer 120 including the high concentration of indium through a multi-layer composite structure. Through this, the crystallinity of the active layer 120 may be improved, and as a result, internal quantum efficiency (IQE) and external quantum efficiency (EQE) of the light emitting device 100 may be maximized.

The light emitting device 100 may include a mesa structure in which a portion of a semiconductor layer is etched. A portion of an upper surface of the first conductivity type semiconductor layer 110 may be exposed around the mesa.

The light emitting device 100 may include a first contact electrode in contact with the first conductivity type semiconductor layer 110 and a second contact electrode in contact with the second conductivity type semiconductor layer 130. The light emitting device 100 may be disposed on one surface of a circuit board and may be electrically connected to the circuit board through the first contact electrode and the second contact electrode.

Meanwhile, the light emitting device 100 described above is a light emitting structure that emits long-wavelength red light by including the high In composition in the well layer 124, and a peak wavelength of emitted light emitted from the active layer 120 may be 600 nm to 650 nm.

In this case, a ratio (Δp/T1) of the peak wavelength λp (nm) to a thickness T1 (nm) from a barrier layer 128 adjacent to the second conductivity type semiconductor layer 120 to the second conductivity type semiconductor layer 120 may have a value between 3.4 and 3.8.

The light emitting device 100 of the present invention emits long-wavelength red light with the peak wavelength range of 620 nm to 640 nm by including the high concentration of indium (In) in the well layer 124, and such a high concentration of indium may be a main cause of accumulating a significant amount of compressive strain in the active layer 120. Accumulated strain may be controlled and the radiation efficiency may be determined depending on the thickness of the second conductivity type semiconductor layer 130 (a p-type semiconductor layer) grown on the active layer 120.

The thickness T1 may mean a total thickness from an upper surface of the barrier layer 128 (i.e., a last barrier layer) positioned on an uppermost portion of the multiple quantum well (MQW) structure to an uppermost surface of the second conductivity type semiconductor layer 130.

When the second conductivity type semiconductor layer 130 is too thin, enormous strain accumulated in the active layer 120 may not be effectively alleviated or dispersed, and thus, crystalline defects may occur. Conversely, when the second conductivity type semiconductor layer 130 becomes too thick, it may itself cause another strain problem or deteriorate crystallinity. Within the thickness-to-peak wavelength ratio (Δp/T1) range of the present invention, the strain of the active layer 120 may be effectively alleviated, thereby maintaining the crystallinity.

In addition, when the thickness T1 increases, an overall resistance of the second conductivity type semiconductor layer 130 increases, which may lower hole injection efficiency and increase the driving voltage (Vf) of the light emitting device 100. A sufficient strain alleviation effect may be obtained while suppressing excessive increase in driving voltage within the thickness-to-peak wavelength ratio (λp/T1) range of the present invention.

In addition, the second conductivity type semiconductor layer 130 is grown at a relatively low temperature so as to prevent thermal damage of the active layer 120, so that it may have poor crystallinity. The thickness T1 specified in the present invention may secure a high-quality second conductivity type semiconductor layer 130 even under this process condition and effectively form a strain alleviation structure such as the buffer line.

According to the thickness-peak wavelength ratio (Δp/T1), problems of strain, crystallinity deterioration, and electrical characteristic deterioration of a red light emitting device 100 including the high concentration indium (In) may be improved, and the external quantum efficiency (EQE) may be maximized.

Alternatively, a ratio (Δd/T1) of the dominant wavelength (λd) to the thickness (nm) from the barrier layer 128 adjacent to the second conductivity type semiconductor layer 130 to the second conductivity type semiconductor layer 130 may have a value between 3.4 and 3.8. The dominant wavelength (Δd) may be shorter than the peak wavelength (λp).

In addition, a ratio (λp/T2) of the peak wavelength (λp) to a thickness T2 (nm) of the well layer 124 may have a value between 135 and 256.

A peak wavelength (λp) of light emitted from the light emitting device 100 may be determined by the thickness T2 and a material composition (e.g., an indium content) of the well layer 124. As the thickness T2 of the well layer 124 becomes larger, an energy level decreases due to a quantum size effect, and light of a longer wavelength may be emitted (red-shift). Therefore, simply increasing the thickness T2 of the well layer 124 may be considered to obtain red light. However, as the well layer 124 becomes larger, a probability of recombination of electrons and holes decreases, which may lower the internal quantum efficiency (IQE), and a degree of shielding of an internal electric field may change depending on an amount of injected current, which may cause an emission wavelength to fluctuate unstably.

Therefore, indiscriminately increasing the well layer thickness T2 for red light may significantly reduce efficiency, and conversely, reducing the thickness T2 may require an excessively high indium (In) composition to obtain a desired red wavelength, thereby increasing crystalline defects.

The present invention may implement ahigh-efficiency red light emitting device 100 without excessive efficiency reduction or crystalline defects by setting the ratio (λp/T2) between the thickness T2 of the well layer and the peak wavelength (λp) to be between 135 and 256.

In addition, a ratio of the peak wavelength (λp) to a thickness (nm) of the pre-strain layer 140 may have a value between 0.8 and 1.

As described above, the pre-strain layer 140 may be a layer for pre-accommodating and alleviating the large lattice stress of the active layer 120 including the high concentration indium (In) to be grown thereon. A total thickness of the pre-strain layer 140 may affect a stress control capability.

By limiting the ratio of the peak wavelength (λp) to the thickness (nm) of the pre-strain layer 140, the crystallinity of the active layer 120 may be maximized and high radiation efficiency may be obtained.

In a case that the ratio of the peak wavelength (λp) to the thickness (nm) of the pre-strain layer 140 exceeds 1, the pre-strain layer 140 is excessively thin, and the thickness of the pre-strain layer 140 may not be sufficient compared to an amount of stress that will occur in the active layer 120 (the longer the wavelength, the greater the stress that will occur). When the pre-strain layer is too thin, it may not be able to effectively absorb or disperse the enormous stress energy generated during the growth of the active layer 120. Accordingly, unbuffered stress may directly generate fatal crystalline defects, such as misfit dislocations, within the active layer 120. These defects may act as non-luminescent recombination centers, thereby severely reducing the internal quantum efficiency (IQE).

In a case that the ratio of the peak wavelength (λp) to the thickness (nm) of the pre-strain layer 140 is less than 0.8, the pre-strain layer 140 is excessively thick, and a quality of the pre-strain layer 140 itself may deteriorate, which may have a negative effect on the active layer 120, and a thin film growth process time may be extended, thereby decreasing productivity and increasing manufacturing costs. In addition, an unnecessarily thick pre-strain layer 140 may cause an increase in the driving voltage (Vf), which may decrease a power efficiency of the light emitting device 100.

The light emitting module according to the present invention may include the light emitting device 100 described above.

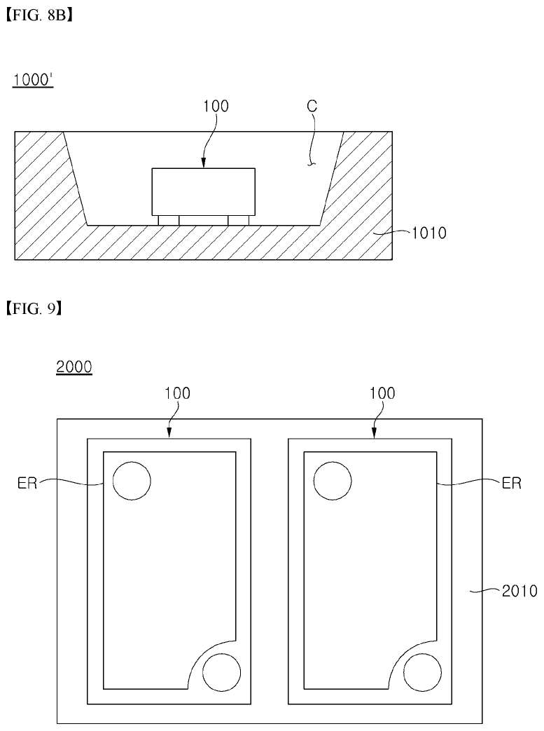

First, FIG. 8A illustrates a light emitting module according to a first embodiment of the present invention, which may be a light emitting package 1000 including at least one light emitting device 100.

The light emitting package 1000 may include at least one light emitting device 100 and a lead frame 1010 on which the light emitting device 100 is mounted. The light emitting device 100 may be electrically connected to an electrode of the lead frame 1010 via a wire W.

The lead frame 1010 may be provided with a cavity C in which the light emitting device 100 is located. A side wall of the lead frame 1010 forming the cavity C may form an inclined surface, and the inclined surface may be a reflection surface on which light emitted from the light emitting device 100 is reflected.

The light emitting package 1000 may further include a molding portion disposed in the cavity C. The molding portion may be a transparent molding. Alternatively, the molding portion may include a wavelength conversion material. Alternatively, the molding portion may further include a light absorbing material, a light reflecting material, or a light scattering material.

Next, a light emitting package 1000′ of FIG. 8B is a modified example of the light emitting package 1000 of FIG. 8A, which may be configured identically or similarly to the light emitting package 1000 of FIG. 8A, except that the light emitting device 100 is soldered to the lead frame 1010 through bumps in a flip-chip form.

Next, FIG. 9 illustrates a light emitting module according to a second embodiment of the present invention, which may be a light emitting module 2000 including at least one light emitting device 100. The light emitting module 2000 may include a substrate 2010 and at least one light emitting device 100 disposed on the substrate 2010.

The light emitting module 2000 may include a plurality of light emitting devices 100. FIG. 9 exemplarily illustrates that the light emitting module 2000 includes two light emitting devices 100, but the present invention is not limited thereto. In FIG. 9, ER shows a light emitting region by the light emitting device 100.

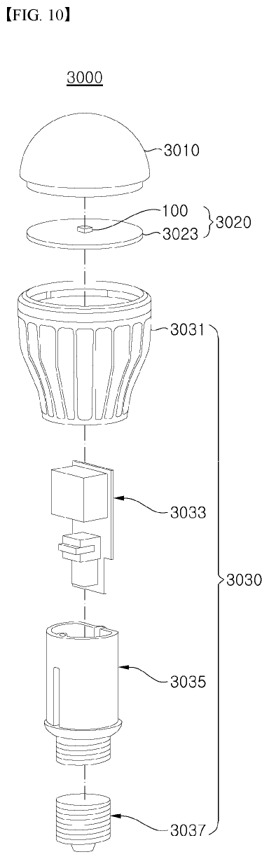

Next, FIG. 10 illustrates a light emitting module according to a third embodiment of the present invention, and the light emitting module may be a lighting apparatus 3000 including at least one light emitting device 100 described above.

Referring to FIG. 10, the lighting apparatus 3000 may include a diffusion cover 3010, a light source module 3020, and a body portion 3030. The body portion 3030 may accommodate the light source module 3020, and the diffusion cover 3010 may be disposed on the body portion 3030 so as to cover an upper portion of the light emitting apparatus module 3020.

The body portion 3030 is not limited to a specific shape as long as it can accommodate and support the light source module 3020 and supply electrical power to the light source module 3020. For example, as illustrated, the body portion 3030 may include a body case 3031, a power supply apparatus 3033, a power case 3035, and a power connection portion 3037.

The power supply apparatus 3033 may be accommodated within the power case 3035 and electrically connected to the light source module 3020, and may include at least one IC chip. The IC chip may adjust, convert or control characteristics of power supplied to the light source module 3020. The power case 3035 may accommodate and support the power supply apparatus 3033, and the power case 3035 with the power supply apparatus 3033 secured therein may be positioned inside the body case 3031. The power connection portion 3037 is disposed at a lower end of the power case 3035, and may be connected to the power case 3035. Accordingly, the power connection portion 3037 may be electrically connected to the power supply apparatus 3033 inside the power case 3035, and may serve as a passage through which external power can be supplied to the power supply apparatus 3033.

The light source module 3020 may include a substrate 3023 and at least one light emitting device 100 disposed on the substrate 3023. The light source module 3020 may be provided in an upper portion of the body case 3031 to be electrically connected to the power supply apparatus 3033.

The substrate 3023 is not limited to a specific substrate as long as it is capable of supporting the light emitting device 100, and may be, for example, a printed circuit board including interconnections. The substrate 3023 may have a shape corresponding to a securing portion on the upper portion of the body case 3031, in order that it may be stably secured to the body case 3031.

The diffusion cover 3010 is disposed on the light emitting device 100, and may be secured to the body case 3031 to cover the light emitting device 100. The diffusion cover 3010 may have a light-transmitting material, and light orientation of the lighting apparatus 3000 may be adjusted through regulation of the shape and optical transmissivity of the diffusion cover 3010. Therefore, the diffusion cover 3010 may be modified into various shapes depending on usage and applications of the lighting apparatus 3000.

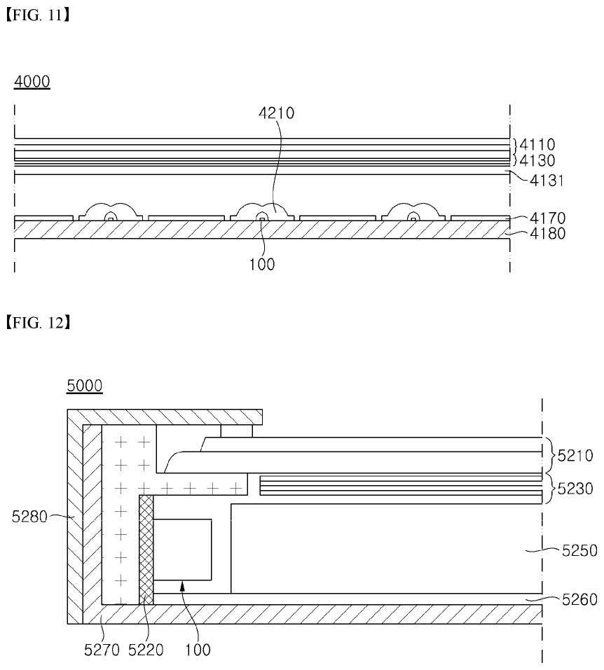

Next, FIG. 11 is a cross-sectional view of a light emitting module according to a fourth embodiment of the present invention, in which the light emitting module may be a display apparatus 4000 including at least one light emitting device 100 described above.

The display apparatus 4000 may include a display panel 4110, a backlight unit that provides light to the display panel 4110, and a panel guide that supports a lower edge of the display panel 4110.

The display panel 4110 is not particularly limited, and may be, for example, a liquid crystal display panel including a liquid crystal layer. A gate driving PCB that supplies a driving signal to the gate line may be further positioned at an edge of the display panel 4110. Herein, the gate drive PCB may be formed on a thin film transistor substrate, instead of being formed on an additional PCB. A pixel of the display panel 4110 may be an LED display implemented by the light emitting device 100 of the present invention. In a case that the display panel 4110 is the LED display, a backlight unit described later may be omitted.

The backlight unit may include a light source module including at least one substrate and a plurality of light emitting devices 100. Furthermore, the backlight unit may further include a bottom cover 4180, a reflection sheet 4170, a diffusion plate 4131, and optical sheets 4130.

The bottom cover 4180 may be opened upwards, and may house the substrate, the light emitting device 100, the reflection sheet 4170, the diffusion plate 4131, and the optical sheets 4130. In addition, the bottom cover 4180 may be coupled to the panel guide. The substrate may be positioned under the reflection sheet 4170, and may be disposed in a form surrounded by the reflection sheet 4170. However, the inventive concepts are not limited thereto, and in a case that a reflection material is coated on a surface thereof, it may be positioned on the reflection sheet 4170. In addition, the substrate may be formed in a plurality of numbers, and disposed in a form in which the plurality of substrates is disposed in a form flush with one another, but the inventive concepts are not limited thereto, and may be formed as a single substrate.

The light emitting devices 100 may be regularly arranged in a certain pattern on the substrate. In addition, a lens 4210 may be disposed on each of the light emitting devices 100, and may improve a uniformity of light emitted from the plurality of light emitting devices 4160.

The diffusion plate 4131 and the optical sheets 4130 are positioned on the light emitting device 100. Light emitted from the light emitting device 100 may be supplied to the display panel 4110 in a form of a surface light source through the diffusion plate 4131 and the optical sheets 4130.

As described above, the light emitting device 100 according to the embodiments of the present invention may be applied to a direct-type display apparatus 4000 such as the present embodiment.

Next, FIG. 12 is a cross-sectional view of a light emitting module according to a fifth embodiment of the present invention, in which the light emitting module may be a display apparatus 5000 including at least one light emitting device 100 described above.

The display apparatus 5000 provided with a backlight unit according to the fifth embodiment includes a display panel 5210 on which an image is displayed, and the backlight unit disposed on a back surface of the display panel 5210 and irradiating light. Furthermore, the display apparatus 5000 may include a frame that supports the display panel 5210 and houses the backlight unit, and covers 5240 and 5280 that surround the display panel 5210.

The display panel 5210 is not particularly limited, and may be, for example, a liquid crystal display panel including a liquid crystal layer. A gate driving PCB that supplies a driving signal to the gate line may be further positioned at an edge of the display panel 5210. Herein, the gate drive PCB may be formed on a thin film transistor substrate, instead of being formed on an additional PCB. The display panel 5210 is secured by the covers 5240 and 5280 positioned over and under the display panel 5210, and the cover 5280 positioned thereunder may be coupled to the backlight unit.

The backlight unit that provides light to the display panel 5210 includes a lower cover 5270 having a partially opened upper surface, a light source module disposed on one inner side of the lower cover 5270, and a light guide plate 5250 positioned in flush with the light source module to convert spot light into surface light. In addition, the backlight unit of the present embodiment may further include optical sheets 5230 positioned on the light guide plate 5250 to diffuse and condense light, and a reflection sheet 5260 disposed under the light guide plate 5250 to reflect light progressing in a lower direction of the light guide plate 5250 toward the display panel 35210.

The light source module includes a substrate 5220 and a plurality of light emitting devices 100 spaced apart at regular intervals on one surface of the substrate 5220. The substrate 5220 is not limited to a specific substrate as long as it supports the light emitting device 100 and is electrically connected to the light emitting device 100, and may be, for example, a printed circuit board.

Light emitted from the light source module may be incident on the light guide plate 5250 and supplied to the display panel 5210 through the optical sheets 5230. Through the light guide plate 5250 and the optical sheets 5230, spot light sources emitted from light emitting devices 100 may be transformed into surface light sources.

As described above, the light emitting device 100 according to the embodiments of the present invention may be applied to an edge-type display apparatus 5000 such as the present embodiment.

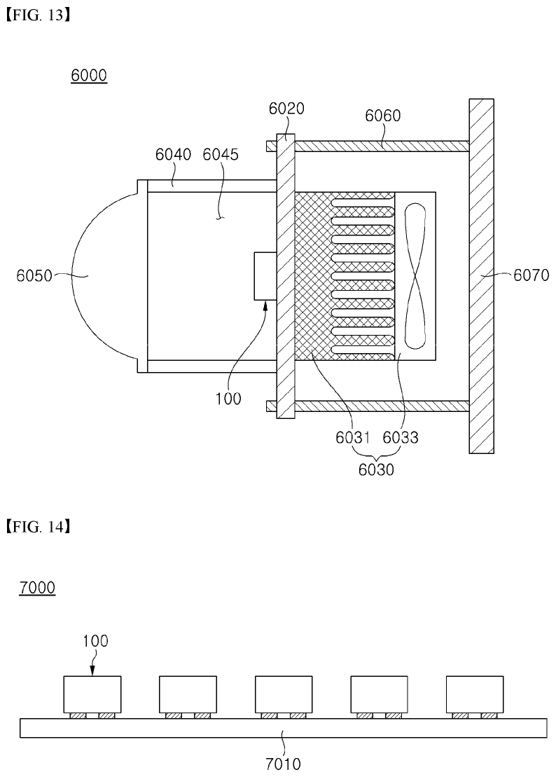

Next, FIG. 13 is a cross-sectional view of a light emitting module according to a sixth embodiment of the present invention, in which the light emitting module may be a head lamp 6000 including at least one light emitting device 100 described above.

Referring to FIG. 13, the head lamp 6000 may include a lamp body 6070, a substrate 6020, the light emitting device 100, and a cover lens 6050. Moreover, the head lamp 6000 may further include a heat dissipation unit 6030, a support rack 6060, and a connection member 6040.

The substrate 6020 may be secured by the support rack 6060 and spaced apart from the lamp body 6070. The substrate 6020 is not limited to a specific substrate as long as it is capable of supporting the light emitting device 100, and may be, for example, a substrate having a conductive pattern such as a printed circuit board. The light emitting device 100 is positioned on the substrate 6020, and may be supported and secured by the substrate 6020. In addition, the light emitting device 100 may be electrically connected to an external power source through the conductive pattern of the substrate 6020.

The cover lens 6050 is positioned on a path along which light emitted from the light emitting device 100 proceeds. For example, as illustrated, the cover lens 6050 may be spaced apart from the light emitting device 100 by the connection member 6040, and may be disposed in a direction in which light emitted from the light emitting device 100 is desired to be provided. A viewing angle and/or color of light from the head lamp 6000 emitted to the outside may be adjusted by the cover lens 6050.

Meanwhile, the connection member 6040 may be disposed so as to secure the cover lens 6050 to the substrate 6020, and also so as to surround the light emitting device 100 to serve as a light guide that provides a light emitting path 6045. In this case, the connection member 6040 may be formed of a light-reflective material, or coated with a light-reflective material. Meanwhile, the heat dissipation unit 6030 may include a heat dissipation fin 6031 and/or a heat dissipation fan 6033, and may release heat generated when a light emitting device 6010 is operated to the outside.

Next, FIG. 15 is a cross-sectional view of a light emitting module according to a seventh embodiment of the present invention, in which the light emitting module may include a circuit board 7010 and at least one light emitting device 100 disposed on one surface of the circuit board 7010.

The light emitting module according to an embodiment of the present invention may form various light emitting apparatuses such as lighting apparatuses, display apparatuses, or others.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100: Light emitting device
101: Growth substrate
110: First conductivity type semiconductor layer
120: Active layer
130: Second conductivity type semiconductor layer
140: Pre-strain layer
1000, 1000′, 2000, 3000, 4000, 5000, 6000, 7000: Light emitting module

1. A light emitting device, comprising:
a first conductivity type semiconductor layer;
a second conductivity type semiconductor layer; and
an active layer disposed between the first conductivity type semiconductor layer and the second conductivity type semiconductor layer, wherein
the active layer comprises a multi quantum well structure of a plurality of well layers and a plurality of barrier layers that are alternately disposed,
a peak wavelength of emitted light emitted from the active layer is 620 nm to 640 nm, and
a ratio of the peak wavelength to a thickness from a barrier layer adjacent to the second conductivity type semiconductor layer to the second conductivity type semiconductor layer has a value between 3.4 and 3.8.

2. The light emitting device of claim 1,
wherein a difference between an In composition (%) of a well layer of the plurality of well layers and an In composition (%) of the second conductivity type semiconductor layer is 20% or more.

3. The light emitting device of claim 2,
wherein the second conductivity type semiconductor layer comprises a buffer line for alleviating lattice stress with the well layer.

4. The light emitting device of claim 3,
wherein the buffer line has a slope with respect to a thickness direction of the second conductivity type semiconductor layer and extends from a first surface of the second conductivity type semiconductor layer toward a second surface of the second conductivity type semiconductor layer.

5. The light emitting device of claim 1,
wherein a ratio of the peak wavelength to a thickness of a well layer of the plurality of well layers has a value between 135 and 256.

6. The light emitting device of claim 1,
wherein the first conductivity type semiconductor layer is a semiconductor layer doped with an n-type dopant, and the second conductivity type semiconductor layer is a semiconductor layer doped with a p-type dopant, and
the light emitting device further comprises a pre-strain layer disposed between the first conductivity type semiconductor layer and the active layer.

7. The light emitting device of claim 6,
wherein a ratio of the peak wavelength to a thickness of the pre-strain layer has a value between 0.8 and 1.

8. The light emitting device of claim 6,
wherein the pre-strain layer comprises a first pre-strain layer disposed on a first surface of the first conductivity type semiconductor layer and including GaN, a second pre-strain layer disposed on a first surface of the first pre-strain layer and including InGaN, and a superlattice pre-strain layer disposed on a first surface of the second pre-strain layer.

9. The light emitting device of claim 8,
wherein the first pre-strain layer comprises a first-1 pre-strain layer and a first-2 pre-strain layer having a thickness smaller than a thickness of the first-1 pre-strain layer.

10. The light emitting device of claim 8,
wherein the first pre-strain layer is doped with Si.

11. The light emitting device of claim 8,
wherein an In composition of the second pre-strain layer has a value between 1% and 10%.

12. The light emitting device of claim 11,
wherein the superlattice pre-strain layer comprises a plurality of pairs in which InGaN and GaN are alternately stacked.

13. The light emitting device of claim 12,
wherein an In composition of the superlattice pre-strain layer is less than or equal to an In composition of the second pre-strain layer.

14. The light emitting device of claim 1,
wherein the active layer further comprises a cap layer disposed between a well layer of the plurality of well layers and a barrier layer of the plurality of barrier layers and including Al.

15. The light emitting device of claim 14,
wherein the cap layer comprises a first cap layer disposed on a first surface of the well layer and including AlN, and a second cap layer disposed on one surface of the first cap layer and including AlGaN.

16. The light emitting device of claim 6,
wherein the first conductivity type semiconductor layer comprises a first-1 conductivity type semiconductor layer including GaN, a first-2 conductivity type semiconductor layer disposed on one surface of the first-1 conductivity type semiconductor layer and including Al, and a first-3 conductivity type semiconductor layer disposed on one surface of the first-2 conductivity type semiconductor layer and including GaN.

17. The light emitting device of claim 6,
wherein the second conductivity type semiconductor layer comprises a second-1 conductivity type semiconductor layer including GaN, a second-2 conductivity type semiconductor layer disposed on one surface of the second-1 conductivity type semiconductor layer and including Al, and a second-3 conductivity type semiconductor layer disposed on one surface of the second-2 conductivity type semiconductor layer and including GaN.

18. A light emitting device, comprising:
a first conductivity type semiconductor layer;
a second conductivity type semiconductor layer; and
an active layer disposed between the first conductivity type semiconductor layer and the second conductivity type semiconductor layer, wherein
the active layer comprises a multi quantum well structure of a plurality of well layers and a plurality of barrier layers that are alternately disposed,
a dominant wavelength of emitted light emitted from the active layer is 610 nm to 630 nm, and
a ratio of the dominant wavelength to a thickness from a barrier layer adjacent to the second conductivity type semiconductor layer to the second conductivity type semiconductor layer has a value between 3.4 and 3.8.

19. The light emitting device of claim 18,
wherein a difference between an In composition (%) of a well layer of the plurality of well layers and an In composition (%) of the second conductivity type semiconductor layer is 20% or more.

20. The light emitting device of claim 19,
wherein the second conductivity type semiconductor layer comprises a buffer line for alleviating lattice stress with the well layer.
